(19) United States
(12) Patent Application Publication
(10) Pub. No.: US 2013/0242511 A1
(43) Pub. Date: Sep. 19, 2013

(54) WIRING BOARD, DISPLAY PANEL, AND ELECTRONIC APPARATUS

(71) Applicant: Takuya Ohishi, Osaka (JP)

(72) Inventor: Takuya Ohishi, Osaka (JP)

(73) Assignee: SHARP KABUSHIKI KAISHA, Osaka (JP)

(21) Appl. No.: 13/883,197

(22) PCT Filed: Nov. 10, 2011
(86) PCT No.: PCT/JP2011/075995

§ 371 Date: May 2, 2013

(30) Foreign Application Priority Data
Nov. 16, 2010 (JP) 2010-255951

(51) Int. Cl. H05K 1/02

(52) U.S. Cl. CPC H05K 1/0292
USPC 361/748; 174/250

(57) ABSTRACT

A wiring substrate of the present invention has, on a first dummy wiring disposing section (105a) in a first lead-out wiring section (105), a dummy wiring line (2) that is formed of a light-shielding metal in positions that correspond to a front and a rear of a bent portion (10) of a wiring line (1) by having an insulating layer therebetween. As a result, sufficient countermeasures against disconnection of the wiring line (1) are taken in the first lead-out wiring section, and a sufficient aperture ratio for seal curing with UV radiation can be ensured.

### TECHNICAL FIELD

The present invention relates to a wiring substrate provided with a dummy wiring line for repairing a wire disconnection.

### BACKGROUND ART

Patent Document 1 discloses a wiring substrate provided with a disconnection repairing dummy wiring line for repairing a wire disconnection. In Patent Document 1, an active matrix substrate in a liquid crystal display panel is described as an example of the wiring substrate.

FIG. 10 is a plan view of a single pixel in a TFT (thin film transistor) array of the active matrix substrate of Patent Document 1.

As shown in FIG. 10, in the active matrix substrate, each of a gate wiring line and a source wiring line connected to a pixel electrode through a TFT has a single layer structure at wiring intersections where the respective wiring lines intersect with each other. However, because a wire disconnection is more likely to occur in the source wiring line that is narrower than the gate wiring line, in areas other than the wiring intersections, the source wiring line has a multi-layer structure in which a dummy wiring line made of a metal is formed under the source wiring line through an insulating layer (not shown).

When the source wiring line is disconnected at the disconnected section shown in FIG. 10, the source wiring line and the dummy wiring line provided therebelow are melted by laser radiation or the like in melt sections, thereby forming a bypass wiring line.

RELATED ART DOCUMENT

### Patent Document

Patent Document 1: Japanese Patent Application Laid-Open Publication “Japanese Patent Application Laid-Open Publication No. H10-319438 (Published on Dec. 4, 1998)”

### SUMMARY OF THE INVENTION

### Problems to be Solved by the Invention

In addition to the source wiring lines formed near pixels, lead-out wiring lines formed between a display region and terminals (terminals connected to a driver IC, for example) are also susceptible to disconnection.

As a countermeasure against the disconnection in the lead-out wiring lines, dummy wiring lines made of a light-shielding metal are formed on the respective wiring lines, as shown in FIG. 11, for example.

With this configuration, when the wiring line is disconnected, for example, the wiring line and the light-shielding metal are melted, thereby forming a bypass wiring line to bypass the disconnected section.

However, as shown in FIG. 11, if the dummy wiring lines for repairing a wire disconnection are formed along the respective wiring lines, a sufficient aperture ratio cannot be ensured in the lead-out wiring section due to the light-shielding properties of the dummy wiring lines. In particular, when the dummy wiring lines are disposed below the wiring lines, that is, on the side closer to an insulating substrate, the dummy wiring lines block UV light radiated to a sealing material in a device model in which UV light is radiated from the TFT substrate side (UV rear surface exposure model), and as a result, the sealing material cannot be cured sufficiently.

The aperture ratio means a ratio of the area of a light transmissive region to the total area of the lead-out wiring section. That is, if the aperture ratio is high, the area of the light transmissive region is made larger, and therefore, it is possible to ensure that sufficient UV light is provided for seal curing by UV radiation. In contrast, if the aperture ratio is low, the area of the light transmissive region is small, and therefore, it is not possible to ensure that sufficient UV light is provided for seal curing by UV radiation.

Thus, with the conventional configuration, sufficient UV light for seal curing by UV radiation cannot be ensured, which prevents the sealing material from being cured sufficiently.

The present invention was made in view of the above-mentioned problems, and an object thereof is to provide a wiring substrate in which dummy wiring lines for repairing a wire disconnection are disposed so as to ensure a sufficient aperture ratio for seal curing by UV radiation while achieving a sufficient countermeasure against a wire disconnection in a lead-out wiring section.

### Means for Solving the Problems

The inventor of the present invention and colleagues conducted studies to solve the above-mentioned problems, and discovered that, even in the same wiring line, a bent portion is more susceptible to an external force, and is more likely to be disconnected than a straight portion. That is, the inventor of the present invention and colleagues discovered that, in a wiring line having a bent portion, a sufficient countermeasure against a wire disconnection can be achieved simply by forming a dummy wiring line for repairing a wire disconnection to cover the bent portion that is more likely to be disconnected. It was also discovered that a space between wiring lines is larger around the bent portion than around a straight portion, which makes it easier to ensure a sufficient aperture ratio.

A wiring substrate of the present invention has: a wiring section in which a plurality of wiring lines are formed; a plurality of terminals to be connected to an external device; and a lead-out wiring section in which a prescribed number of wiring lines are led out from the wiring section so as to be connected to the terminals, wherein at least one wiring line in the lead-out wiring section has a bent portion, and wherein the wiring line having the bent portion has a dummy wiring line formed therefor with an insulating layer interposed therebetween, the dummy wiring line being made of a light-shielding metal and being in positions at least corresponding to a front and a rear of the bent portion.

With this configuration, a light-shielding metal as a dummy wiring line is provided for at least the wiring line having the bent portion with an insulating layer interposed therebetween in positions that correspond to a front and a rear of the bent portion. This provides a countermeasure against a wire disconnection in the bent portion. As a result, in the lead-out wiring section, by providing a countermeasure against a wire disconnection in the bent portion that is susceptible to a wire disconnection, a sufficient countermeasure against a wire disconnection in the lead-out wiring section can be achieved.

The dummy wiring line is formed near the bent portion of a wiring line. Because a space between wiring lines is larger around the bent portion than around a straight portion, a sufficient aperture ratio can be ensured with ease. Therefore, even if the dummy wiring line slightly protrudes from the wiring line, the aperture ratio is not likely to be affected.

Further, because the dummy wiring line is formed only in a region near the bent portion of a wiring line, it is possible to increase the aperture ratio as compared with a case in which a dummy wiring line is formed along the entire wiring line.

As a result, by forming a dummy wiring line in an appropriate position with respect to a wiring line having a bent portion, it is possible to ensure a sufficient aperture ratio for seal curing by UV radiation in the lead-out wiring section.

As described above, it is possible to provide a wiring substrate in which dummy wiring lines for repairing a wire disconnection are disposed so as to ensure a sufficient aperture ratio for seal curing by UV radiation while achieving a sufficient countermeasure against a wire disconnection in the lead-out wiring section.

### Effects of the Invention

A wiring substrate of the present invention has: a wiring section in which a plurality of wiring lines are formed; a plurality of terminals to be connected to an external device; and a lead-out wiring section in which a prescribed number of wiring lines are led out from the wiring section so as to be connected to the terminals, wherein at least one wiring line in the lead-out wiring section has a bent portion, and wherein a dummy wiring line made of a light-shielding metal is formed for the wiring line having the bent portion through an insulating layer at least in positions corresponding to a front and a rear of the bent portion.

With this configuration, it is possible to achieve an effect of providing a wiring substrate in which dummy wiring lines for repairing a wire disconnection are disposed so as to ensure a sufficient aperture ratio for seal curing by UV radiation while achieving a sufficient countermeasure against a wire disconnection in the lead-out wiring section.

### BRIEF DESCRIPTION OF THE DRAWINGS

FIG. 1 is a schematic diagram of a wiring structure of a lead-out wiring section of a wiring substrate of Embodiment 1 of the present invention.

FIG. 2 is a schematic plan view of an active matrix substrate having the lead-out wiring section of FIG. 1.

FIG. 3 is an enlarged view of a main part of the lead-out wiring section of FIG. 2.

FIG. 4 is a schematic diagram showing a wiring structure of the lead-out wiring section.

FIG. 5 is an enlarged view of the lead-out wiring section of FIG. 4, showing a state before a dummy wiring line is formed.

FIG. 6 is an enlarged view of FIG. 5, showing a state after a dummy wiring line is formed.

FIG. 7 is an enlarged view of the enlarged view of FIG. 6.

FIG. 8 is a schematic diagram showing a wiring structure in a lead-out wiring section of a wiring substrate of Embodiment 2 of the present invention.

FIG. 9 is a schematic diagram showing a wiring structure in a lead-out wiring section of a wiring substrate of Embodiment 3 of the present invention.

FIG. 10 is a schematic plan view of a wiring substrate in which conventional dummy wiring lines are formed.

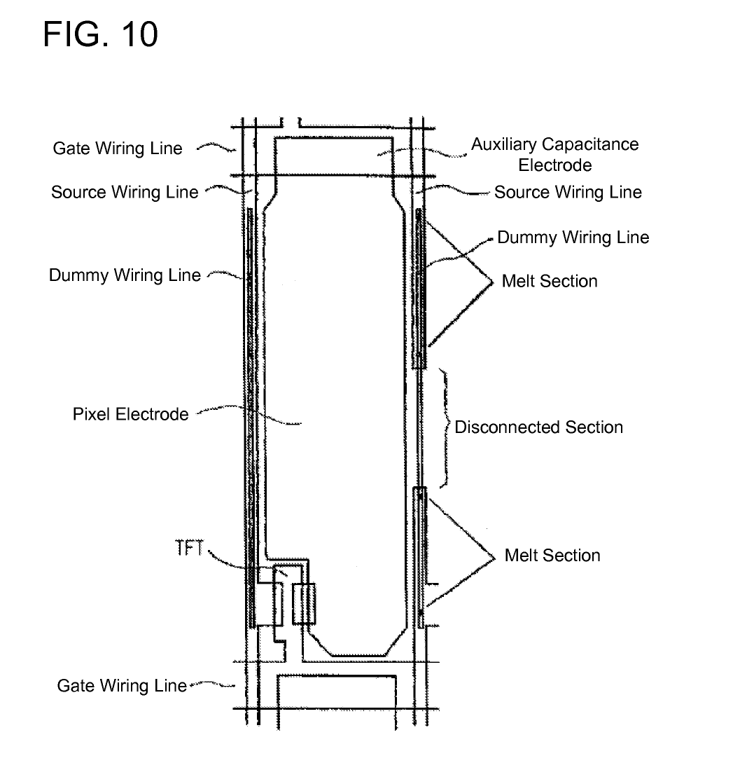

FIG. 11 is a diagram illustrating a disconnection repair using conventional dummy wiring lines.

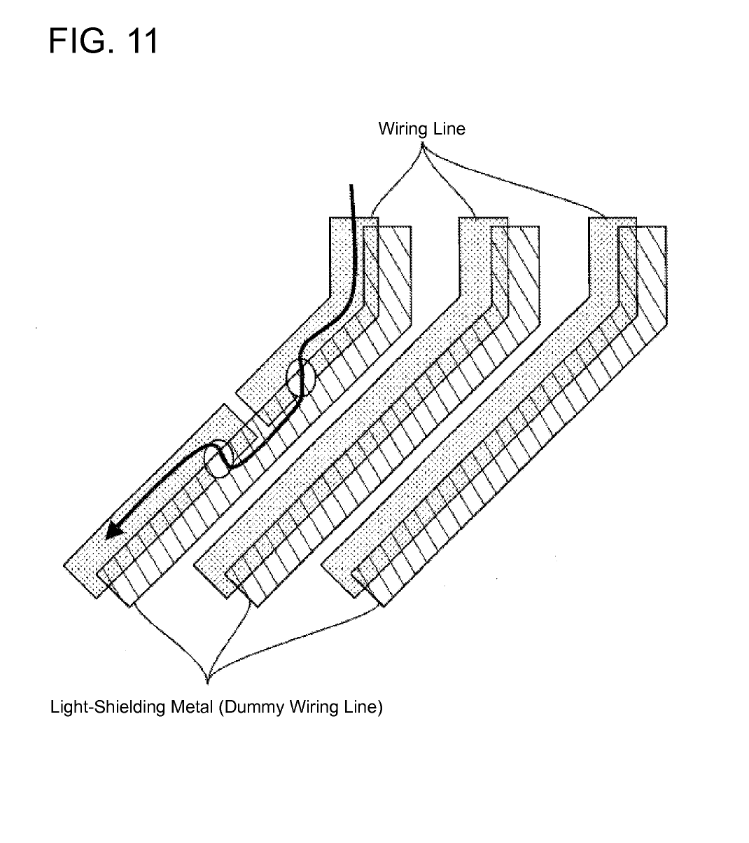

### DETAILED DESCRIPTION OF EMBODIMENTS

### Embodiment 1

An embodiment of the present invention will be explained below. In the embodiment below, a liquid crystal display panel will be described as an example of a display panel of the present invention.

<Liquid Crystal Display Panel>

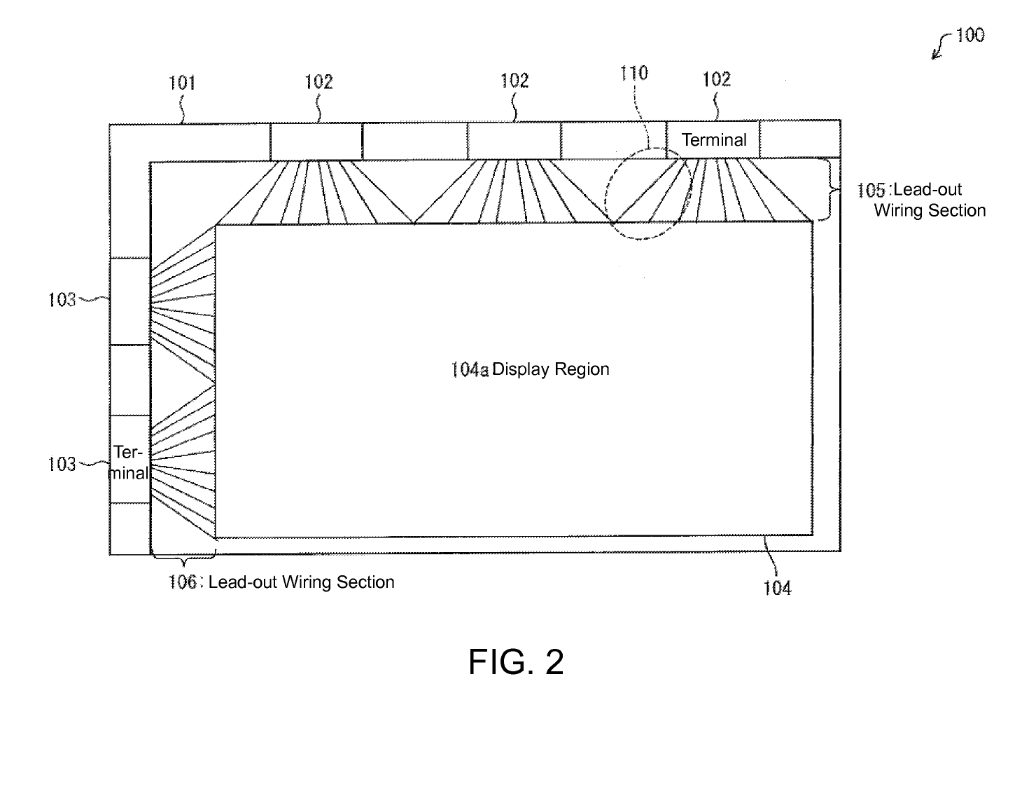

FIG. 2 is a schematic plan view showing a configuration of a liquid crystal display panel 100 of the present embodiment.

As shown in FIG. 2, the liquid crystal display panel 100 includes an active matrix substrate 101, an opposite substrate (not shown) disposed so as to face the active matrix substrate 101, and liquid crystal sandwiched therebetween.

In the active matrix substrate 101, a plurality of first terminals 102, a plurality of second terminals 103, and a display section 104 are formed on a light transmissive insulating substrate (such as a glass substrate).

The first terminals 102 are terminals connected to a source driver that is a driver circuit (external device) for driving the liquid crystal display panel 100.

The second terminals 103 are terminals connected to a gate driver that is a driver circuit (external device) for driving the liquid crystal display panel 100.

Although not shown in the figure, the display section 104 includes source wiring lines and gate wiring lines arranged in a matrix, TFTs (thin film transistors) disposed for the respective intersections of these wiring lines, and pixel electrodes, thereby displaying a desired image in a display region 104a (wiring section).

Between the first terminals 102 and the display section 104, a first lead-out wiring section 105 is formed in which a prescribed number of wiring lines out of a plurality of source wiring lines in the display region 104a are led out so as to be connected to the first terminals 102.

Between the second terminals 103 and the display section 104, a second lead-out wiring section 106 is formed in which a prescribed number of wiring lines out of a plurality of gate wiring lines in the display region 104a are led out so as to be connected to the second terminals 103.

<Lead-Out Wiring Section>

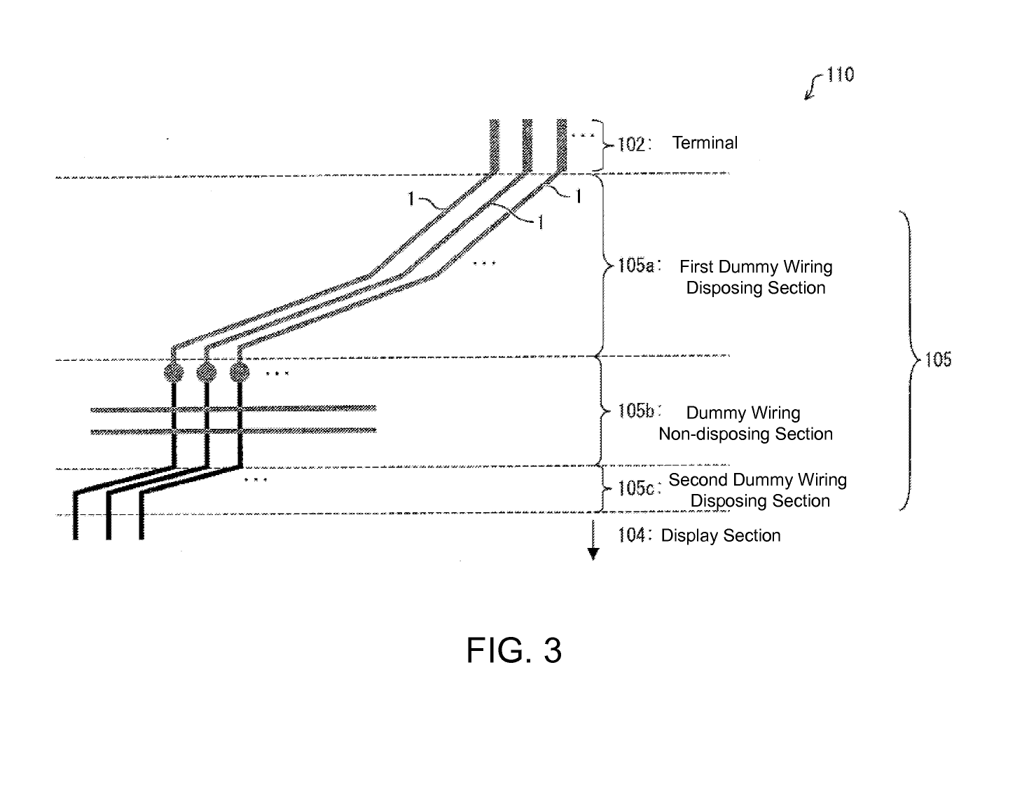

FIG. 3 shows an enlarged region 110 that is an enlarged portion of the first lead-out wiring section 105 of the liquid crystal display panel 100 of FIG. 2.

Wiring lines 1 in the first lead-out wiring section 105 are formed between the display section 104 and the first terminals 102, and a space between respective wiring lines differs depending on the locations where the wiring lines are formed. Dummy wiring lines for repairing a wire disconnection, which will be later described, are provided in a section where the space between wiring lines is large.

As shown in FIG. 3, in the present embodiment, the first lead-out wiring section 105 is divided into three regions. That is, the first lead-out wiring section 105 includes a first dummy wiring disposing section 105a, a dummy wiring non-disposing section 105b, and a second dummy wiring disposing section 105c in this order from the side of the first terminals 102.

In the first dummy wiring disposing section 105a and the second dummy wiring disposing section 105c, the wiring lines 1 do not intersect with other wiring lines and have a single layer structure. Therefore, even if dummy wiring lines for repairing a wire disconnection are disposed so as to overlap the respective wiring lines 1 in these two sections, it does not cause a problem, and it is possible to form an appropriate bypass route when a wire disconnection occurs. This is because, in those regions, even though the dummy wiring lines are disposed so as to overlap the respective wiring lines 1, there is only an insulating film interposed therebetween, and therefore, when wiring lines are melted to repair a wire disconnection, other wiring lines or layers are not melted together with the wiring line 1, the dummy wiring line, and the insulating film.

On the other hand, the dummy wiring non-disposing section 105b has a multi-layer structure, including a switching portion in which S-G metals are switched and a crossing portion in which the wiring lines 1 intersect with other wiring lines. Therefore, if dummy wiring lines are disposed in this region, the number of layers would be further increased, and when the wiring lines are melted to repair a wire disconnection, other wiring lines that intersect with the wiring lines 1 and the dummy wiring lines would also be melted, possibly causing an undesired electrical connection to be formed between wiring lines.

That is, if the dummy wiring lines are formed in at least one of the first dummy wiring disposing section 105a and the second dummy wiring disposing section 105c, then it means that the dummy wiring lines are formed in a single layer region in which the wiring lines do not intersect with other wiring lines in the first lead-out wiring section 105 in positions that correspond to the respective bent portions. In this case, because the dummy wiring lines are formed in positions that correspond to the respective bent portions in a single layer region in which the wiring lines do not intersect with other wiring lines in the first lead-out wiring section 105, it is possible to prevent an undesired electrical connection between wiring lines when the wiring lines are melted to repair a wire disconnection.

An example of providing dummy wiring lines in the first dummy wiring disposing section 105a in the first lead-out wiring section 105 will be explained below.

<Arrangement of Dummy Wiring Lines>

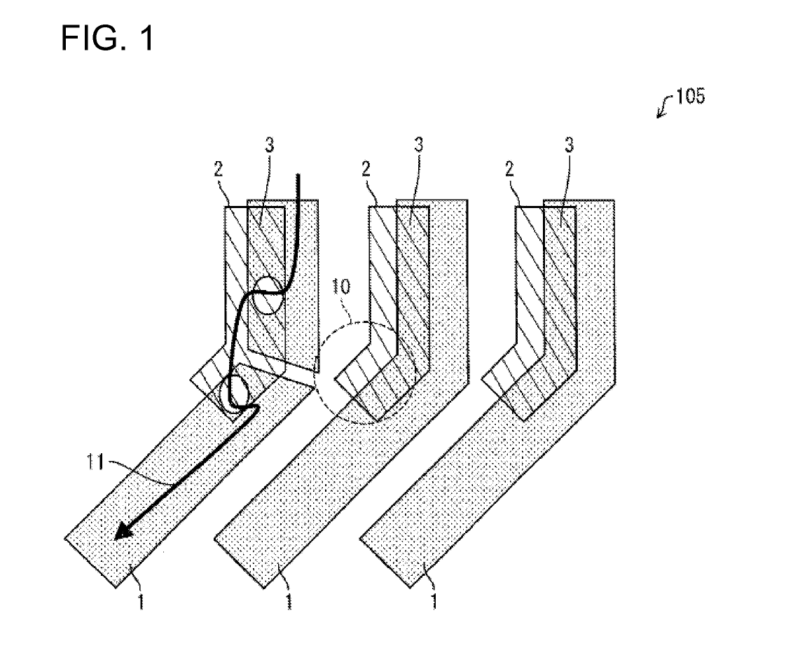

FIG. 1 is a schematic diagram showing a wiring structure in the first dummy wiring disposing section 105a.

In the first dummy wiring disposing section 105a, due to the arrangement of the wiring lines 1, each wiring line 1 has at least one bent portion 10. The bent portion 10 is formed in at least one wiring line 1 in the first lead-out wiring section 105.

In the first dummy wiring disposing section 105a, as shown in FIG. 1, a dummy wiring line 2 is formed only in positions corresponding to a front and a rear of the bent portion 10 of the wiring line 1. This is because, in the lead-out wiring section 105, a disconnection of the wiring line 1 is more likely to occur in the bent portion 10 of the wiring line 1 due to ESD (electrostatic discharge).

Electrical charges tend to be concentrated in an angled shape such as the bent portion 10 of the wiring line 1, and therefore, electrical discharge is more likely to start from this portion. When the discharge occurs, the pattern in that portion is damaged. Therefore, in addition to the bent portion 10 of the wiring line 1, portions in the wiring lines with an angled shape tend to have wire disconnections due to ESD, and thus, it is preferable to also form dummy wiring lines in such portions.

The dummy wiring lines 2 are made of a light-shielding metal, and an insulating film is formed between the dummy wiring lines 2 and the wiring lines 1. As a result, normally, the wiring lines 1 and the dummy wiring lines 2 are insulated from each other.

When the wiring line 1 is disconnected, a laser beam is radiated to spots in the wiring line 1 and the dummy wiring line 2, thereby melting them to establish electrical connection therebetween. As a result, in the disconnected section (bent portion 10) of the wiring line 1, a bypass route 11 is formed to restore an electrical connection in the disconnected wiring line 1.

As described above, because the dummy wiring line 2 made of a light-shielding metal is formed in positions that correspond to a front and a rear of the bent portion 10 of the wiring line 1 through an insulating layer (not shown), a countermeasure against a wire disconnection in the bent portion 10 is achieved. As a result, by providing a countermeasure against a wire disconnection for the bent portions 10 where wire disconnections are more likely to occur in the first lead-out wiring section 105, a sufficient countermeasure against a wire disconnection in the first lead-out wiring section 105 can be achieved.

Because the dummy wiring line 2 is formed in positions that correspond to a front and a rear of the bent portion 10 of the wiring line 1, it is possible to increase an aperture ratio as compared with a case in which a dummy wiring line is formed along the entire wiring line as in a conventional example. As a result, by forming the dummy wiring line 2 in an appropriate position with respect to the wiring line 1 having the bent portion 10, it is possible to ensure a sufficient aperture ratio for seal curing by UV radiation in the first lead-out wiring section 105.

As a result, it is possible to achieve an effect of ensuring a sufficient aperture ratio for seal curing by UV radiation while achieving a sufficient countermeasure against a wire disconnection in the first lead-out wiring section 105.

In order to ensure the aperture ratio, it is preferable to form the dummy wiring lines 2 in a region where a space between the wiring lines 1 is large. Because a space between the wiring lines 1 can be made larger in the bent portion 10 of the wiring line 1 due to a layout, the dummy wiring line 2 can be disposed therein with ease.

As described above, when a larger space is available around the bent portion 10, by disposing the dummy wiring line 2 so as to be closer to the region with a larger space, a sufficient aperture ratio can be ensured even if respective layers (a layer in which the wiring line 1 is formed and a layer in which the dummy wiring line 2 is formed) are misaligned to each other.

In order to prevent the aperture ratio from being reduced by the dummy wiring line 2 protruding to a space, it is preferable to maximize the width of an overlapping portion 3 formed by disposing the wiring line 1 and the dummy wiring line 2 so as to partially overlap each other.

<Dummy Wiring Line Forming Method>

A forming method for dummy wiring lines in the first lead-out wiring section 105 will be explained.

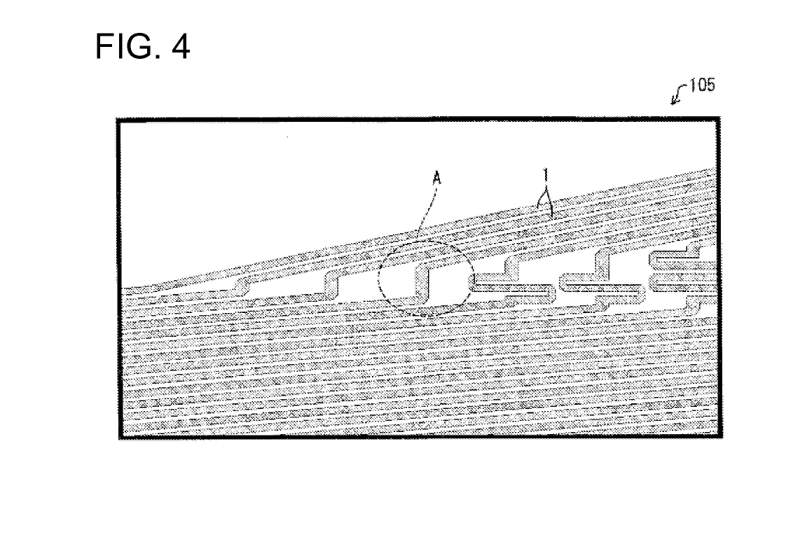

FIG. 4 is a diagram showing a wiring structure of the wiring lines 1 in the actual first lead-out wiring section 105.

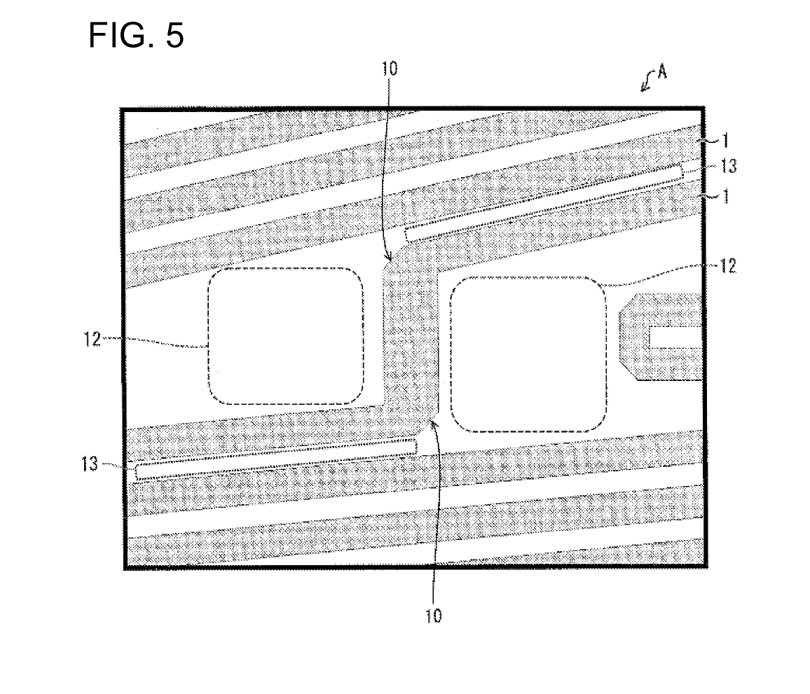

As shown in FIG. 4, in the first lead-out wiring section 105, the wiring lines 1 are arranged at substantially even intervals, except for certain areas. In the approximate center of FIG. 4, the wiring line 1 is formed so as to be bent. FIG. 5 is an enlarged view of the bent portion.

FIG. 5 shows an example in which the bent portions 10 are formed at two locations in the wiring line 1.

Near the two bent portions 10, first regions 12 having a large area and a second region 13 having a smaller area than that of the first regions 12 are present.

In the first lead-out wiring section 105, the first regions 12 are regions that are respectively adjacent in the line width direction to the straight portion of the wiring line 1 between the two bent portions 10, and the second region 13 is a region that is located near the bent portion 10 of the wiring line 1 and that is parallel to an adjacent wiring line 1.

Normally, only the second regions 13 are formed between the respective wiring lines 1, but in the first lead-out wiring section 105, the wiring line 1 has the bent portions 10 due to the layout, and near the bent portions 10, the first regions 12 having a larger area than the second region 13 are formed.

When the dummy wiring line 2 is formed around the bent portion 10 of the wiring line 1, because of the presence of a relatively large space (first region 12), the aperture ratio is not significantly lowered even if the dummy wiring line 2 is formed so as to protrude from the wiring line 1.

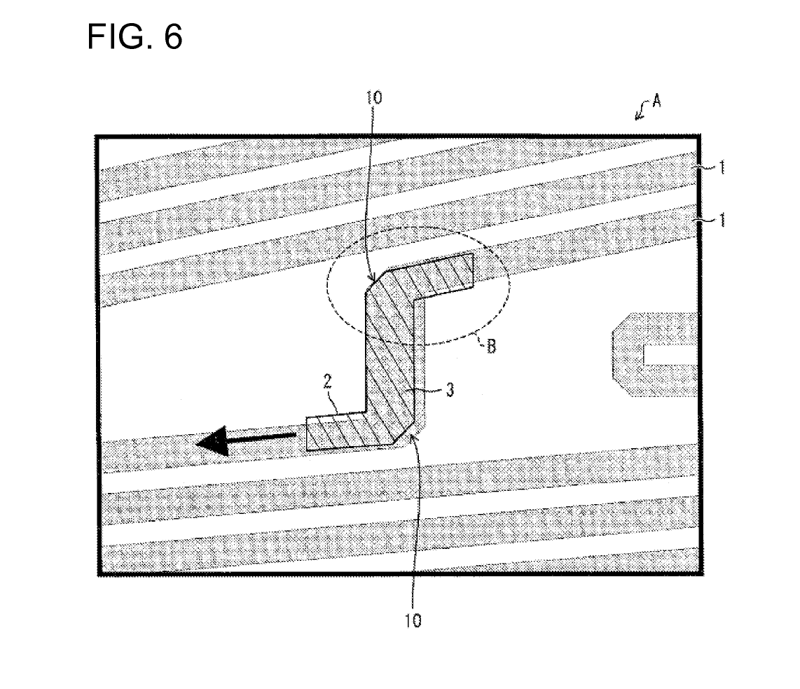

FIG. 6 shows an example in which the dummy wiring line 2 is formed near the bent portions 10 in the wiring structure of FIG. 5.

In FIG. 6, the wiring line 1 and the dummy wiring line 2 overlap each other in the overlapping portion 3. The dummy wiring line 2 is formed so as to protrude from the wiring line 1 in a direction that does not significantly affect the aperture ratio. As described above, because the aperture ratio is sufficiently high in spaces around the bent portions 10, it is not necessary to align the dummy wiring line 2 precisely to the wiring line 1 so as not to protrude therefrom, and instead, it is possible to form the dummy wiring line 2 with a certain margin.

Below, a formation of the dummy wiring line 2 will be described in detail.

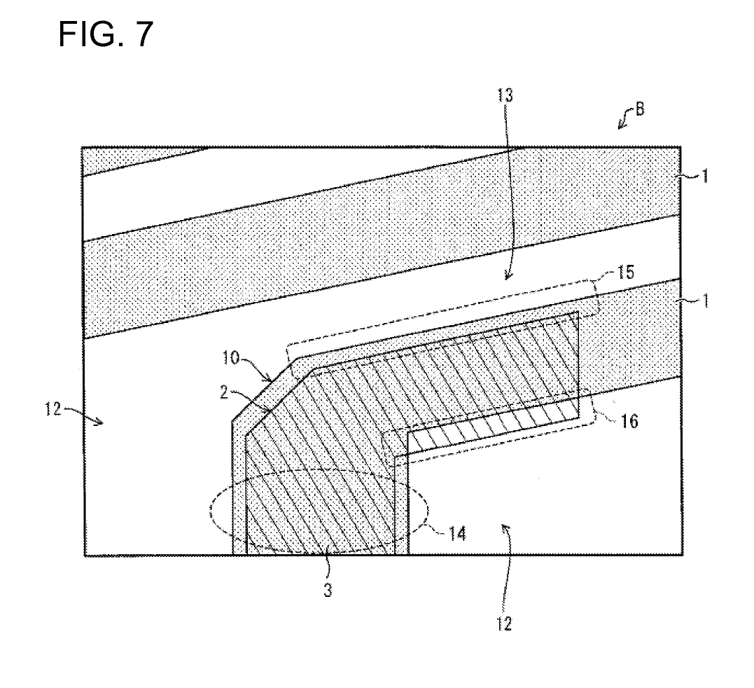

FIG. 7 is an enlarged view of an area near one bent portion 10 of the two bent portions 10 of the wiring line 1 shown in FIG. 6. The other bent portion 10 has a similar configuration.

As shown in FIG. 7, in portions adjacent to the first regions 12 and the second region 13, the dummy wiring line 2 is disposed so as to form a first overlapping region 14 in which the dummy wiring line 2 is completely covered by the wiring line 1, and so as to form a third overlapping region 16 in which the dummy wiring line 2 protrudes toward the first region 12 from the wiring line 1. In a portion adjacent to the second region 13, the dummy wiring line 2 is disposed so as to form a second overlapping region 15 in which the dummy wiring line 2 does not protrude toward the second region 13 from the wiring line 1.

Because the first region 12 is larger than the second region 13, even though the dummy wiring line 2 protrudes slightly from the wiring line 1 as in the third overlapping region 16, a reduction in the aperture ratio is not caused. On the other hand, if the dummy wiring line 2 protrudes from the wiring line 1 toward the second region 13, the aperture ratio would be significantly reduced, and therefore, as in the second overlapping region 15, it is preferable to form the dummy wiring line 2 so as not to protrude from the wiring line 1.

As described above, the dummy wiring line 2 is formed so as not to protrude from the wiring line 1 toward the second region 13, and therefore, it is possible to ensure the aperture ratio.

The dummy wiring line 2 may be formed so as to protrude from the wiring line 1 toward the first region 12, and therefore, it is possible to increase the line width of the dummy wiring line 2. As a result, an effect of making it easier to form the dummy wiring line 2 can be achieved.

In the region having the first regions 12 on both sides, the dummy wiring line 2 is formed so as to be completely covered by the wiring line 1. However, because both sides of the wiring line 1 are adjacent to the first regions 12, it is possible to form the dummy wiring line 2 so as to slightly protrude from the wiring line 1.

As described above, with the configuration in which the dummy wiring line 2 is formed for the wiring line 1 in the manner shown in FIG. 7, even when the wiring line 1 and the dummy wiring line 2 are slightly misaligned to each other, a reduction in aperture ratio can be prevented, and the line width of the dummy wiring line 2 can be made wider to a certain extent. This configuration makes it possible to address the misalignment of the dummy wiring line 2 to the wiring line 1 in all directions of up, down, left and right.

In the present embodiment, in order to ensure the aperture ratio in the first lead-out wiring section 105, the dummy wiring line 2 was formed for the wiring line 1 having the bent portion 10 only in positions that correspond to a front and a rear of the bent portion 10, but the present invention is not limited to such. If it is possible to ensure that sufficient UV light for seal curing is radiated in the first lead-out wiring section 105, that is, if the aperture ratio meets the standard, the dummy wiring line 2 may be formed in an area other than the area around the bent portion 10. Below, an example of forming the dummy wiring line 2 in an area other than the area around the bent portion 10 when the aperture ratio meets the standard will be explained.

### Embodiment 2

Another embodiment of the present invention will be explained below.

In the present embodiment, an example of forming the dummy wiring line 2 for other portions of a wiring line than the bent portion 10 in the first lead-out wiring section 105 in the liquid crystal display panel 100 described in Embodiment 1 above will be explained.

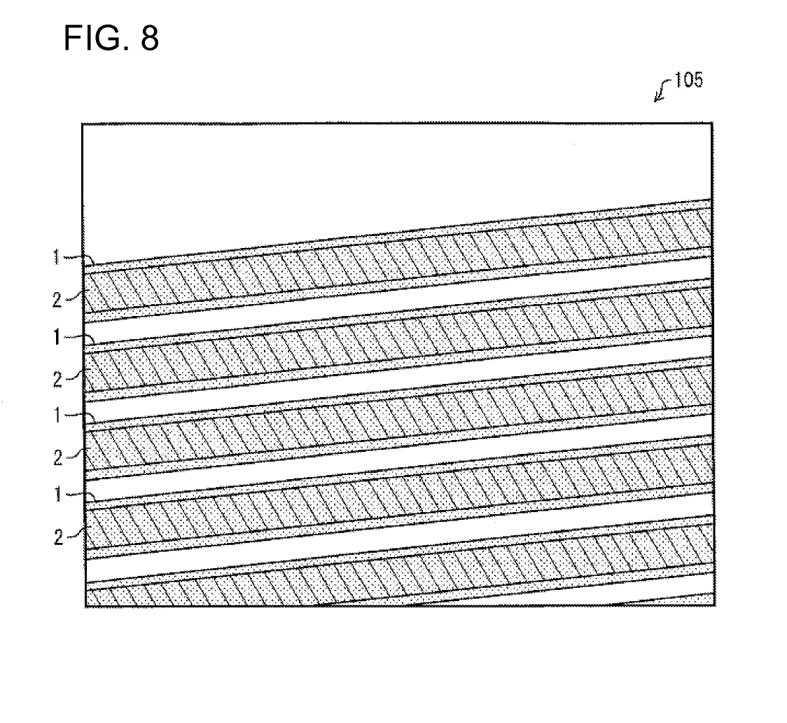

FIG. 8 shows a wiring structure in which the dummy wiring lines 2 are formed for other portions of the wiring lines 1 than the bent portion 10 in the first lead-out wiring section 105.

The wiring structure shown in FIG. 8 illustrates an example of forming the dummy wiring line 2 so as to be completely covered by the wiring line 1 when the wiring line 1 has a sufficient line width.

In this case, the dummy wiring line 2 is completely covered by the wiring line 1, and therefore, even if the dummy wiring line 2 and the wiring line 1 are slightly misaligned to each other, the dummy wiring line 2 is unlikely to protrude from the wiring line, which can prevent a reduction in aperture ratio.

The line width of the wiring line 1 can be made sufficiently wide when a lead-out region between the terminals and the display section is made larger for the same resolution and the same panel size, for example, and the larger this region is, the wider the wiring line 1 can be. As described, when the wiring line 1 can be made wider, the dummy wiring line 2 can be completely covered by the wiring line 1.

### Embodiment 3

Another embodiment of the present invention will be explained below.

In the present embodiment, an example of forming the dummy wiring line 2 for other portions of a wiring line than the bent portion 10 in the first lead-out wiring section 105 in the liquid crystal display panel 100 described in Embodiment 1 above will be explained.

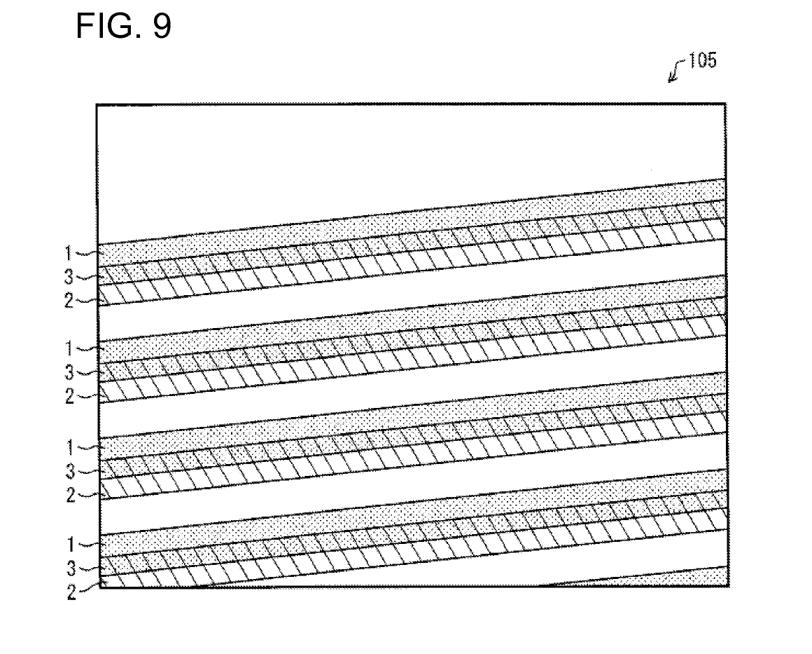

FIG. 9 shows a wiring structure in which the dummy wiring lines 2 are formed for the respective wiring lines 1 in areas other than the bent portion 10 in the first lead-out wiring section 105.

The wiring structure shown in FIG. 9 illustrates an example in which the dummy wiring line 2 is formed so as to partially overlap the wiring line 1, forming an overlapping portion 3 that becomes a portion to be melted by laser (melt portion) when a wiring line space between the respective wiring lines 1 is sufficiently large.

As described above, when there is a sufficiently wide wiring line space between the respective wiring lines 1, a sufficient aperture ratio can be ensured, and therefore, even when the dummy wiring line 2 is formed so as to partially overlap the wiring line 1 in an area other than the bent portion 10, it does not cause a significant reduction in aperture ratio.

Also, with the above-mentioned configuration, because the dummy wiring line 2 does not have to be aligned to the wiring line 1, the precise positioning between the dummy wiring line 2 and the wiring line 1 is not necessary.

The wiring line space between the respective wiring lines 1 can be made sufficiently large when a lead-out region between the terminals and the display section is made larger for the same resolution and the same panel size, for example.

In the lead-out region, a region allocated for one wiring line 1 (wiring line pitch) can be divided to an area occupied by a wiring line 1 and an area between the wiring line 1 and an adjacent wiring line 1 (wiring line space), and therefore, if the lead-out region is made larger, the area allocated for the wiring line space can also be made larger. That is, the wiring line space between the respective wiring lines 1 can be made sufficiently large.

As described above in Embodiments 2 and 3, by forming the dummy wiring lines 2 in other areas in addition to the bent portions 10 of the wiring lines 1, a wire disconnection of the wiring lines 1 in the first lead-out wiring section 105 and the second lead-out wiring section 106 can be reliably repaired.

In each of the embodiments above, the active matrix substrate 101 was described as an example of the wiring substrate of the present invention, but the present invention is not limited to such, and can be applied to any wiring substrate in which UV light is radiated from the rear surface side thereof to cure a sealing material in a sealing portion.

The liquid crystal display panel 100 was described as an example of the display panel equipped with the wiring substrate of the present invention, but the present invention is not limited to such. Other display panels such as an organic EL (electroluminescence) panel and an inorganic EL panel may also be used.

The wiring substrate of the present invention may be provided to an electronic device other than display panels.

It is preferable that the dummy wiring line for a wiring line having a bent portion be formed only in positions corresponding to a front and a rear of the bent portion.

In this case, because the dummy wiring line for the wiring line having a bent portion is formed only in positions corresponding to a front and a rear of the bent portion, the aperture ratio can be reliably made larger as compared with a case in which a dummy wiring line is formed along the entire wiring line as in a conventional configuration.

As a result, it is possible to achieve an effect of ensuring a sufficient aperture ratio for seal curing by UV radiation in the lead-out wiring section.

In the lead-out wiring section, when a region formed between an adjacent wiring line that is adjacent to the wiring line having the bent portion and the bent portion is a first region, and a region formed between a straight portion of the wiring line having the bent portion and the adjacent wiring line is a second region, it is preferable that the dummy wiring line be formed so as to protrude from the wiring line toward the first region in an area in which the wiring line having the bent portion is adjacent to the first region, and so as not to protrude from the wiring line toward the second region in an area in which the wiring line having the bent portion is adjacent to the second region.

The first region is a region formed between the bent portion and an adjacent wiring line that is adjacent to the wiring line having the bent portion, and therefore has a relatively large area. On the other hand, the second region is a region formed between the straight portion of the wiring line having the bent portion and the adjacent wiring line, and therefore has a relatively small area.

By forming the dummy wiring line so as to protrude from the wiring line toward the first region in an area adjacent to the first region, and so as not to protrude from the wiring line toward the second region in an area adjacent to the second region, it is possible to ensure a sufficient aperture ratio in the second region because the dummy wiring line does not protrude thereto, and it is possible to make the dummy wiring line wider in the first region because the dummy wiring line may protrude thereto.

Also, this eliminates a need for precise positioning between the dummy wiring line and the wiring line.

Therefore, with the above-mentioned configuration, even when the wiring line and the dummy wiring line are slightly misaligned to each other, a reduction in aperture ratio can be prevented, and the line width of the dummy wiring line can be made wider to a certain extent. In this configuration, precise positioning of the dummy wiring line to the wiring line is not necessary, and it is possible to address a misalignment in all directions of up, down, left, and right.

It is preferable that the dummy wiring line be formed in a single layer region in which the wiring line does not intersect with other wiring lines in the lead-out wiring section.

In this case, because the dummy wiring line is formed in a single layer region in which the wiring line does not intersect with other wiring lines in the lead-out wiring section, it is possible to avoid an undesired electrical connection between the wiring line and other wiring lines when melting wiring lines to repair a wire disconnection.

It is preferable that the dummy wiring line be formed in a position that allows a desired aperture ratio to be ensured in the lead-out wiring section.

The desired aperture ratio in the lead-out wiring section means a sufficient aperture ratio to allow a seal to be cured by UV radiation in a configuration in which a sealing material is to be cured by UV radiation, for example.

As described, in the above-mentioned configuration, a dummy wiring line can be formed in any position as long as a sufficient aperture ratio for seal curing by UV radiation can be ensured, and therefore, an effect of increasing a degree of freedom in design can be achieved.

It is preferable that the dummy wiring line be made narrower than the wiring line in the lead-out wiring section.

In this case, the dummy wiring line is completely covered by the wiring line, and therefore, even if the dummy wiring line and the wiring line are slightly misaligned to each other, the dummy wiring line is unlikely to protrude from the wiring line, which can prevent a reduction in aperture ratio.

When a space between wiring lines in the lead-out wiring section is greater than a prescribed space, it is preferable that the dummy wiring line be formed so as to partially overlap the wiring line.

In this case, the dummy wiring line and the wiring line do not have to be completely aligned to each other, and therefore, precise positioning between the dummy wiring line and the wiring line is not necessary.

It is preferable that the wiring substrate be used as a wiring substrate of a display panel such as a liquid crystal display panel or an organic EL panel.

The present invention is not limited to each embodiment described above, and various modifications can be made without departing from the scope of the claims. Therefore, embodiments obtained by appropriately combining the techniques disclosed in different embodiments are included in the technical scope of the present invention.

### INDUSTRIAL APPLICABILITY

The present invention can be applied to an electronic device having a wiring substrate in which UV light needs to be radiated from the rear surface thereof to cure a sealing material.

### DESCRIPTION OF REFERENCE CHARACTERS

1 wiring line
2 dummy wiring line
10 bent portion
11 bypass route
12 first region
13 second region
14 first overlapping region
15 second overlapping region
16 third overlapping region
100 liquid crystal display panel (display panel)
101 active matrix substrate (wiring substrate)
102 first terminal
103 second terminal
104 display section
104a display region (wiring section)
105 first lead-out wiring section (lead-out wiring section)
105a first dummy wiring disposing section
105b dummy wiring non-disposing section
105c second dummy wiring disposing section
106 second lead-out wiring section (lead-out wiring section)
110 enlarged region

1. A wiring substrate having: a wiring section in which a plurality of wiring lines are formed; a plurality of terminals to be connected to an external device; and a lead-out wiring section in which a prescribed number of wiring lines are led out from the wiring section so as to be connected to the terminals,
wherein at least one wiring line in the lead-out wiring section has a bent portion, and
wherein the wiring line having the bent portion has a dummy wiring line formed therefor under or above said wiring line with an insulating layer interposed therebetween, the dummy wiring line being made of a light-shielding metal and being in positions at least corresponding to a front and a rear of the bent portion.

2. The wiring substrate according to claim 1,
wherein the dummy wiring line for the wiring line having the bent portion is formed only in positions corresponding to a front and a rear of the bent portion.

3. The wiring substrate according to claim 1,
wherein, in the lead-out wiring section,
when a region formed between an adjacent wiring line that is adjacent to the wiring line having the bent portion and said bent portion is a first region, and a region formed between a straight portion of the wiring line having the bent portion and the adjacent wiring line is a second region,
the dummy wiring line protrudes from the wiring line toward the first region in an area where the wiring line having the bent portion is adjacent to the first region, and the dummy wiring line does not protrude from the wiring line toward the second region in an area where the wiring line having the bent portion is adjacent to the second region.

4. The wiring substrate according to claim 1,
wherein the dummy wiring line is formed in a single layer region in which the wiring lines in the lead-out wiring section do not intersect with other wiring lines.

5. The wiring substrate according to claim 1,
wherein the dummy wiring line is formed in a position that allows a desired aperture ratio to be ensured in the lead-out wiring section.

6. The wiring substrate according to claim 5,
wherein the dummy wiring line has a smaller line width than that of the wiring lines in the lead-out wiring section.

7. The wiring substrate according to claim 5,
wherein, when a space between wiring lines in the lead-out wiring section is larger than a prescribed space, a dummy wiring line is formed so as to at least partially overlap one of the wiring line.

8. A display panel, comprising the wiring substrate according to claim 1.

9. An electronic device, comprising the wiring substrate according to claim 1.
